(19) United States
(12) Patent Application Publication
(10) Pub. No.: US 2026/0182406 A1
(43) Pub. Date: Jun. 25, 2026

(54) MONOLITHIC MICROWAVE INTEGRATED CIRCUIT WITH THERMALLY DISSIPATIVE INTERPOSER

(71) Applicant: Qorvo US, Inc., Greensboro, NC (US)

(72) Inventors: Tarak A. Railkar, Carrollton, TX (US); Lidia C. El Bouanani, Richardson, TX (US); Jeffrey M. Miller, Allen, TX (US)

(21) Appl. No.: 19/376,311

(22) Filed: Oct. 31, 2025

Related U.S. Application Data
(60) Provisional application No. 63/762,407, filed on Feb. 24, 2025.
(60) Provisional application No. 63/738,178, filed on Dec. 23, 2024.

(51) Int. Cl. H10W 70/63; H10W 20/20; H10W 40/10; H10W 80/00; H10W 90/00

(52) U.S. Cl. CPC H10W 70/635; H10W 20/20; H10W 40/10; H10W 80/312; H10W 90/794

(57) ABSTRACT

A monolithic microwave integrated circuit (MMIC) device is provided. The MMIC device includes a MMIC die with an active circuit layer, a first substrate material, and at least one conductive through-semiconductor via (TSV) extending completely through the first substrate material from a top side to a bottom side of the MMIC die. The MMIC device also includes a thermally dissipative interposer including a second substrate material different from the first substrate material and electrically insulating at an operating voltage of the MMIC die, and at least one conductive via, pad, or trace in electrical contact with the at least one conductive TSV or the active circuit layer.

### CROSS REFERENCE TO RELATED APPLICATIONS

This application claims the priority benefit of U.S. Provisional Patent Application No. 63/762,407, filed February 24, 2025, and U.S. Provisional Patent Application No. 63/738,178 filed, December 23, 2024, both of which are hereby expressly incorporated by reference in their entirety as though fully set forth herein.

### TECHNICAL FIELD

The subject matter described herein relates to devices, systems, and methods for providing heat dissipation, electrical interconnects, and mechanical support to a monolithic microwave integrated circuit (MMIC). This MMIC with thermally dissipative interposer has particular but not exclusive utility for high-power radio frequency (RF) applications and phased-array antennas.

### BACKGROUND

A monolithic microwave integrated circuit (MMIC) chip may be referred to as a die, and may for example be fabricated with copper or gold traces on a silicon (Si), gallium arsenide (GaAs) or gallium nitride (GaN) wafer. In some cases, a MMIC die may be packaged in a durable housing or chip-scale package. However, in other cases, it may be desirable to supply a MMIC to an RF equipment manufacturer as a bare die. With a significant increase in the power handling levels of MMICs over the past several decades, it is sometimes desirable to mount the MMIC to a heat spreader, e.g., a mechanical support component that is electrically insulating (or a high-bandgap material) but thermally conducting, such that heat generated by the MMIC may be transmitted to all parts of the heat spreader and either dissipated into the environment or transferred to a heat sink or cooling system. Such a heat spreader may in some cases be referred to as a “tab”, and a bare MMIC die mounted to the heat spreader may be referred to as a “tabbed” MMIC.

The information included in this Background section of the specification, including any references cited herein and any description or discussion thereof, is included for technical reference purposes only and is not to be regarded as subject matter by which the scope of the disclosure is to be bound.

### SUMMARY

Disclosed is a monolithic microwave integrated circuit (MMIC) with thermally dissipative interposer which provides interconnect and fanout capability to a MMIC die, along with mechanical support, while dissipating heat generated by the MMIC die during operation. The MMIC die includes at least one conductive through-semiconductor via (TSV), and the thermally dissipative interposer includes at least one conductive via, pad, or trace in electrical contact with the TSV or with the active circuit layer of the MMIC die. The MMIC with thermally dissipative interposer disclosed herein has particular, but not exclusive, utility for high-power radio frequency systems and phased-array antennas.

One general aspect of the MMIC with thermally dissipative interposer includes a monolithic microwave integrated circuit (MMIC) device. The monolithic microwave integrated circuit includes a MMIC die that may include: an active circuit layer, a first substrate material, and at least one conductive through-semiconductor via (TSV) extending completely through the first substrate material from a top side to a bottom side of the MMIC die. The MMIC device also includes a thermally dissipative interposer that may include: a second substrate material different from the first substrate material and electrically insulating at an operating voltage of the MMIC die, and at least one conductive via, pad, or trace in electrical contact with the at least one conductive TSV or the active circuit layer.

Implementations may include one or more of the following features. In some embodiments, the first substrate material is silicon, gallium arsenide, or gallium nitride, or the second substrate material is silicon carbide, aluminum nitride, or diamond. In some embodiments, the second substrate material has a thermal conductivity of at least at least 200 W/mK. In some embodiments, the second substrate material has a fracture toughness of between 2.0 and 6.8 MPa m0.5. In some embodiments, the at least one conductive via, pad, or trace may include a conductive via extending completely through the second substrate material from a top side to a bottom side of the thermally dissipative interposer; or where the at least one conductive via, pad, or trace may include a routing layer. In some embodiments, the MMIC device may include a redistribution layer attached to the thermally dissipative interposer and in electrical contact with the at least one conductive via, pad, or trace. In some embodiments, the at least one conductive TSV extends through the active circuit layer or where the at least one conductive TSV extends through the first substrate material adjacent to the active circuit layer. In some embodiments, the redistribution layer may include at least one of a routing layer, an edge conductor, an internal conductor, or an insulating region.

One general aspect includes a method for packaging a monolithic microwave integrated circuit (MMIC). The method includes providing a MMIC die that may include: an active circuit layer, a first substrate material, at least one conductive through-semiconductor via (TSV) extending completely through the first substrate material from a top side to a bottom side of the MMIC die. The method also includes providing a thermally dissipative interposer that may include: a second substrate material different from the first substrate material and electrically insulating at an operating voltage of the MMIC die, and at least one conductive via, pad, or trace. The method also includes bonding the MMIC die to the thermally dissipative interposer such that the at least one conductive via, pad, or trace is in electrical contact with the at least one conductive TSV or the active circuit layer.

Implementations may include one or more of the following features. In some embodiments, the first substrate material is silicon, gallium arsenide, or gallium nitride, or the second substrate material is silicon carbide, aluminum nitride, or diamond. In some embodiments, the second substrate material has a thermal conductivity of at least at least 200 W/mK or a fracture toughness of between 2.0 and 6.8 MPa m0.5. In some embodiments, the at least one conductive via, pad, or trace may include a conductive via extending completely through the second substrate material from a top side to a bottom side of the thermally dissipative interposer, or the at least one conductive via, pad, or trace may include a routing layer. In some embodiments, the method may include providing a redistribution layer attached to the thermally dissipative interposer and in electrical contact with the at least one conductive via, pad, or trace. In some embodiments, the at least one conductive TSV extends through the active circuit layer or where the at least one conductive TSV extends through the first substrate material adjacent to the active circuit layer. Implementations of the described techniques may include hardware, a method or process, or computer software on a computer-accessible medium.

One general aspect includes a wireless device that includes a monolithic microwave integrated circuit (MMIC) device, which may include: a MMIC die which may include: an active circuit layer, a first substrate material, at least one conductive through-semiconductor via (TSV) extending completely through the first substrate material from a top side to a bottom side of the MMIC die. The wireless device also includes a thermally dissipative interposer that may include: a second substrate material different from the first substrate material and electrically insulating at an operating voltage of the MMIC die; and at least one conductive via, pad, or trace in electrical contact with the at least one conductive TSV or the active circuit layer.

Implementations may include one or more of the following features. In some embodiments, the first substrate material is silicon, gallium arsenide, or gallium nitride, or the second substrate material is silicon carbide, aluminum nitride, or diamond. In some embodiments, the second substrate material has a thermal conductivity of at least at least 200 W/mK. In some embodiments, the second substrate material has a fracture toughness of between 2.0 and 6.8 MPa m0.5. In some embodiments, the at least one conductive via, pad, or trace may include a conductive via extending completely through the second substrate material from a top side to a bottom side of the thermally dissipative interposer; or where the at least one conductive via, pad, or trace may include a routing layer. In some embodiments, the wireless device may include a redistribution layer attached to the thermally dissipative interposer and in electrical contact with the at least one conductive via, pad, or trace.

This Summary is provided to introduce a selection of concepts in a simplified form that are further described below in the Detailed Description. This Summary is not intended to identify key features or essential features of the claimed subject matter, nor is it intended to limit the scope of the claimed subject matter. A more extensive presentation of features, details, utilities, and advantages of the MMIC with thermally dissipative interposer, as defined in the claims, is provided in the following written description of various embodiments of the disclosure and illustrated in the accompanying drawings.

### BRIEF DESCRIPTION OF THE DRAWINGS

Illustrative embodiments of the present disclosure will be described with reference to the accompanying drawings, of which:

FIG. 1 is a side cross-sectional view of a thermally dissipative interposer, in accordance with at least one embodiment of the present disclosure.

FIG. 2 is a top perspective view of an example MMIC that includes a MMIC die mounted to a thermally dissipative interposer, in accordance with at least one embodiment of the present disclosure.

FIG. 3 is a side cross-sectional view of an example MMIC that includes a MMIC die bonded to a thermally dissipative interposer, in accordance with at least one embodiment of the present disclosure.

FIG. 4 is a top perspective view of an example MMIC that includes a MMIC die mounted to a thermally dissipative interposer, in accordance with at least one embodiment of the present disclosure.

FIG. 5 is a side cross-sectional view of an example MMIC that includes a MMIC die bonded to a thermally dissipative interposer, in accordance with at least one embodiment of the present disclosure.

FIG. 6 is a side cross-sectional view of an example MMIC that includes two MMIC dies and bonded to a thermally dissipative interposer, in accordance with at least one embodiment of the present disclosure.

FIG. 7 is a side cross-sectional view of an example MMIC that includes a MMIC die bonded to a thermally dissipative interposer that includes five redistribution layers (RDLs), in accordance with at least one embodiment of the present disclosure.

FIG. 8 is a schematic, diagrammatic view of an electronic device or a wireless device comprising a MMIC, in accordance with at least one embodiment of the present disclosure.

### DETAILED DESCRIPTION

In accordance with at least one embodiment of the present disclosure, a MMIC with thermally dissipative interposer is disclosed which provides the functionality of both a heat spreader and an interposer, while providing robust mechanical support for the MMIC die.

In some cases, a MMIC die may be mounted to an interposer that allows contacts on the top or bottom surface of the MMIC to be connected to other components (including other MMICs) without the need for wire bonding. Such interposers are typically made of silicon with gold or copper traces, and may be considered thermally insulating rather than thermally dissipative, particularly at the high heat fluxes generated by a MMIC. Silicon is also a moderately robust material, but its thermal conductivity can be a limiting factor for some high-power applications. By contrast, the thermally dissipative interposer disclosed herein is made from an electrically insulating, thermally conductive material such as a wide-bandgap material. Example materials include but are not limited to silicon carbide (SiC), aluminum nitride, or diamond, all of which are mechanically much tougher than traditional interposer materials such as silicon. For example, the fracture toughness of SiC is 2.5-6.8 MPa m^{0.5}, the fracture toughness of aluminum nitride is 4.0-4.6 MPa m^{0.5}, and the fracture toughness of diamond is around 2.0 MPa m^{0.5}, whereas the fracture toughness of silicon (Si) is 0.7-1.3 MPa m^{0.5}. Similarly, the electrical resistance of SiC is between 10⁵ and 10⁷ ohm-cm, vs. 10³ to 10⁴ ohm-cm. for undoped Si. For the purposes of this document, the term “electrically insulative” refers to any device or material that does not conduct electricity at the operating voltage of any devices, traces, etc. attached to the device or material.

In addition to an integrated thermal management solution, current and forward-looking applications are pointing to a need for integrating an interconnect solution to MMIC dies. Disclosed herein is a novel method of configuring and fabricating an "Interconnect Tabbed MMIC” or “MMIC with thermally dissipative interposer”. With this innovation, a MMIC fabricator can supply a fine-pitch interconnect-enabled and thermally dissipative MMIC that equipment manufacturers can then integrate into their products. Accordingly, this disclosure describes a method of integrating an advanced, fine-pitch interconnect-enabled and thermally dissipative MMIC that supports not only higher levels of thermal performance than bare MMICs, but also provides a reliable mechanism of advanced interconnect for the customer's next-level assembly and integration.

Followed below are some of the key technical benefits of the solution outlined in this disclosure. The thermally dissipative interposer provides mechanical support to MMICs, as they get thinner from the current 100um down to 50um, 25um and beyond. Mechanical handling is an important aspect of reducing yield loss, and as the thickness of MMICs continues to reduce, the thermally dissipative interposer provides mechanical robustness and additional benefits as are outlined herein. The thermally dissipative interposer also allows a methodology for fan-out routing where required, thus supporting tighter interconnect pitch and smaller MMICs, without adversely impacting assembly considerations. As an added advantage, the customer can benefit from improved RF performance through the smaller die and shorter resultant signal paths. The thermally dissipative interposer also supports integration of multi-MMIC for non-packaged, bare-die sales. The tabbing process can support integration of two or more dies onto the thermally dissipative interposer, so as to deliver added functionality to unpackaged MMIC product offerings. This also shortens signal paths across multiple dies, by leveraging more advanced fabrication technologies for the interposer.

The thermally dissipative interposer leverages wafer-fab like capabilities for line/space as well as via-definitions – which are usually superior compared to those from traditional laminates or other chip-carrier substrates. This capability allows for the MMICs to be routed more efficiently, thus reducing signal path in several scenarios, resulting in enhancements to the electrical / RF performance. This also enables superior, integrated thermal management solutions for bare MMIC die sales. When the MMIC with thermally dissipative interposer is properly designed and fabricated, its thermal performance can be significantly superior to that of the bare-die itself. The methodology described herein also enhances mechanical reliability performance through three-dimensional heterogeneous integration (3DHI). Use of advanced fab-like processes and technologies can make the MMIC with thermally dissipative interposer mechanically superior and more robust, thus increasing reliability.

These descriptions are provided for exemplary purposes only, and should not be considered to limit the scope of the MMIC with thermally dissipative interposer. Certain features may be added, removed, or modified without departing from the spirit of the claimed subject matter.

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

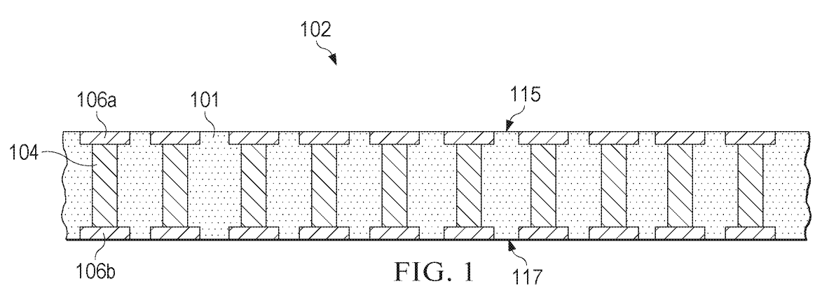

FIG. 1 is a side cross-sectional view of a thermally dissipative interposer 102, in accordance with at least one embodiment of the present disclosure. In the example shown in FIG. 1, the thermally dissipative interposer 102 (also known as a tab, heat spreader, interconnect fabric, etc.) includes a substrate material 101 such as SiC that provides electrical insulation at the operating voltages of a MMIC, but also provides high thermal conductivity (e.g., 490 W/mK for SiC, vs. 140 W/mK for silicon – a 3.5x improvement) and high mechanical toughness (e.g., SiC offers 1.9-9.7 times as much fracture toughness as silicon). Additionally, the substrate material 101 crystalline structure may be configured in a manner that provides enhanced thermal conductivity. For example, dopants or impurities might be present in the substrate material 101 affecting resistivity and/or thermal dissipative properties of SiC alone. The concentration of the impurities would be present according to the desired properties. An interposer made from SiC thus offers capabilities not demonstrated by, nor contemplated for, traditional interposers made from silicon. Thus, the thermally dissipative interposer offers clear advantages over existing interposers. For purposes of this document, “thermally dissipative” shall mean a material or component with a thermal conductivity of at least 200 W/mK (e.g., between 200 and infinity W/mK).

In the example shown in FIG. 1, the thermally dissipative interposer 102 includes “hot” (e.g., electrically conductive and isolated from the electrical ground plane) vias 104 that extend completely through the substrate material 101, from the top surface 115 to the bottom surface 117, and are terminated by top contacts or pads 106a and bottom contacts or pads 106b. In an example, the vias 104 are plated with an electrically conductive material such as copper but retain a hollow core, and the contacts or pads 106a, 106b are donut shaped deposits of the same conductive material, with a hole through the middle that aligns with the hollow core of the vias. In other examples, the vias are entirely filled with the conductive material (e.g., copper or conductive epoxies), and the contacts or pads 106a, 106b are also solid. However, hollow vias and contacts may be preferable, as they allow conductive pillars or posts to be used to make contact between components places on the top and bottom surfaces of the interposer 102, without the need for soldering or thermal bonding. In either case, the vias 104 and contacts 106a, 106b allow devices or components on the top surface 115 to be in electrical communication (e.g., power, signal, ground, etc.) with devices or components on the bottom surface 117, while heat generated by these devices or components is dissipated by the thermally conductive substrate material 101. This interconnect capability is not present in, nor contemplated for, existing heat spreaders. Thus, the thermally dissipative interposer offers clear advantages over existing heat spreaders.

Before continuing, it should be noted that the examples described above are provided for purposes of illustration, and are not intended to be limiting. Other devices and/or device configurations may be utilized to carry out the operations described herein.

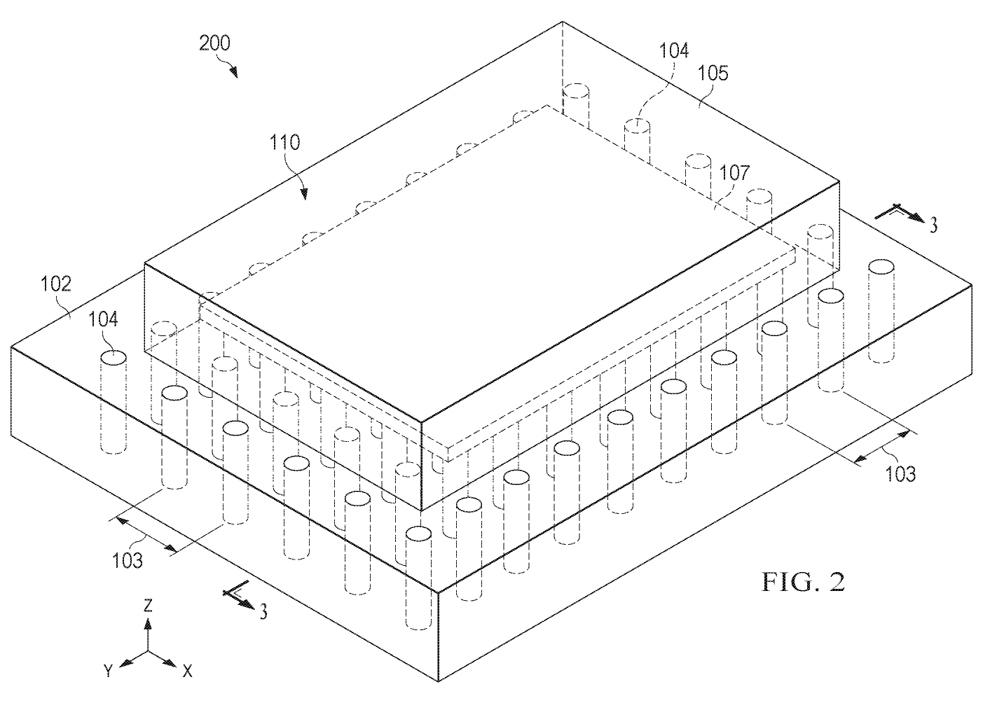

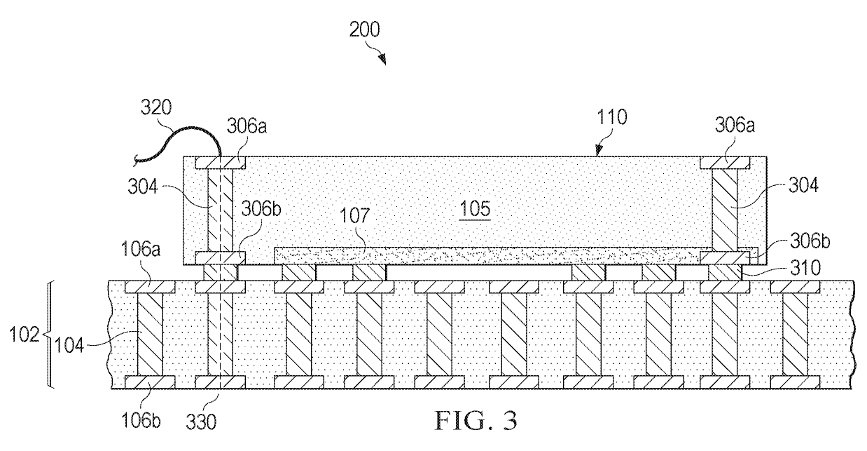

FIG. 2 is a top perspective view of an example MMIC 200 that includes a MMIC die 110 mounted to a thermally dissipative interposer 102, in accordance with at least one embodiment of the present disclosure. As shown above in FIG. 1, the thermally dissipative interposer 102 includes vias 104 that extend completely through the interposer 102, from the top surface to the bottom surface, with a pitch or spacing 103 that can be selected to maximize fanout capabilities. However, unlike FIG. 1, a MMIC die 110 has been attached to the thermally dissipative interposer 102. The MMIC die 110 includes a semiconductor wafer or substrate 105 and an active circuit plane 107. In the example shown in FIG. 2, the active circuit plane 107 is placed face-down on the thermally dissipative interposer 102, such that at least one contact on the active circuit plane 107 is in electrical contact with at least one via 104 of the thermally dissipative interposer 102, as shown below in FIG. 3.

FIG. 3 is a side cross-sectional view of an example MMIC 200 that includes a MMIC die 110 bonded to a thermally dissipative interposer 102, in accordance with at least one embodiment of the present disclosure. As shown above in FIG. 3, the MMIC die 110 is mounted face-down to the thermally dissipative interposer 102. This arrangement may be advantageous because such a tabbed MMIC not only simplifies handling due to mechanical robustness but is also able to support higher levels of integration along the z-dimensions by supporting stacking of additional components. In some cases, a dam material may be dispensed around the sides of the MMIC to form an air cavity between the active circuit plane 107 and the surface of 102. In this manner, not only the quality factor (Q) is optimally affected, but mechanical stability is provided to the arrangement. As will be familiar to a person of ordinary skill in the art, the active circuit plane 107 may include traces, components, pads, etc., to facilitate the functioning of the MMIC.

The active circuit plane 107 of the MMIC die 110 makes contact with the top contacts 106a of the thermally dissipative interposer 102 via conductive connectors 310, which may for example be copper posts, solder bumps, thermal bonds, or otherwise. In the example shown in FIG. 3, he MMIC die 110 also includes two “hot” (e.g., electrically conductive) through-semiconductor vias (TSVs), each with a top contact or pad 306a and a bottom contact or pad 306b. One of the TSVs 304 is shown as being outside of or separate from the active circuit plane 107 of the MMIC die 110, and one TSV 304 is shown as penetrating the active circuit plane 107, but it is understood that all, some, or none of the TSVs may extend through the active circuit plane 107.

The MMIC die 110 can thus be electrically connected to other components or devices (including other MMICs or MMIC dies) through the thermally dissipative interposer 102, without the need for bond wires. However, in the example shown in FIG. 3, a bond wire 320 extends from one of the top contacts 306a of the MMIC die 110, that can be used to electrically connect the top contact 306a to another component or device, which may be part of, or separate from, the MMIC 200.

Because the vias 104 and 304 are electrically conductive, the bond wire 320 is electrically connected through the top contact 306a, through-semiconductor via 304, bottom contact 306b, conductive connector 310, top contact 106a, via 104, and bottom contact 106b, to point 330 on the bottom surface of the thermally dissipative interposer 102. Thus, it can be seen that both the top and bottom surfaces of the MMIC die 110 can be in electrical contact with the top and bottom surfaces of the thermally dissipative interposer 102, and thus that devices or components electrically connected to either side of the MMIC die 110 can be in electrical communication with devices or components connected to either side of the thermally dissipative interposer 102. This flexibility allows for the MMIC die to be integrated with a variety of different components, devices, or systems in myriad ways.

As seen in the schematic FIG. 3, the MMIC in this innovation disclosure can include a wire-bondable and/or a flip-chip die. Further, given their intended use with high-performance, 3D heterogeneously integrated (3DHI) applications, the MMIC may include TSV and hot-vias. The MMIC can have one or more contact pads that are interconnected with one or more corresponding contact pads on the top surface of the thermally dissipative interposer, as shown schematically in FIG. 3. The contact pads on the MMIC die provide mechanical, electrical, and/or thermal path with the contact pads on the thermally dissipative interposer.

In one embodiment, the thickness of the pads on the MMIC die and/or the thermally dissipative interposer can be of the order of tens of – or several tens of – micrometers, thus resembling a ‘stud / pillar’ 310, that is then attached to establish the interconnect.

In another embodiment, the thickness of these pads can be as small as sub-micron dimensions, where the bonding is established by leveraging techniques such as thermo-compression bonding (TCB) and its variants or reflow based technologies, where a suitably thick layer of solder material – such as tin (Sn), tin-silver (SnAg) or other suitable metallurgy is leveraged.

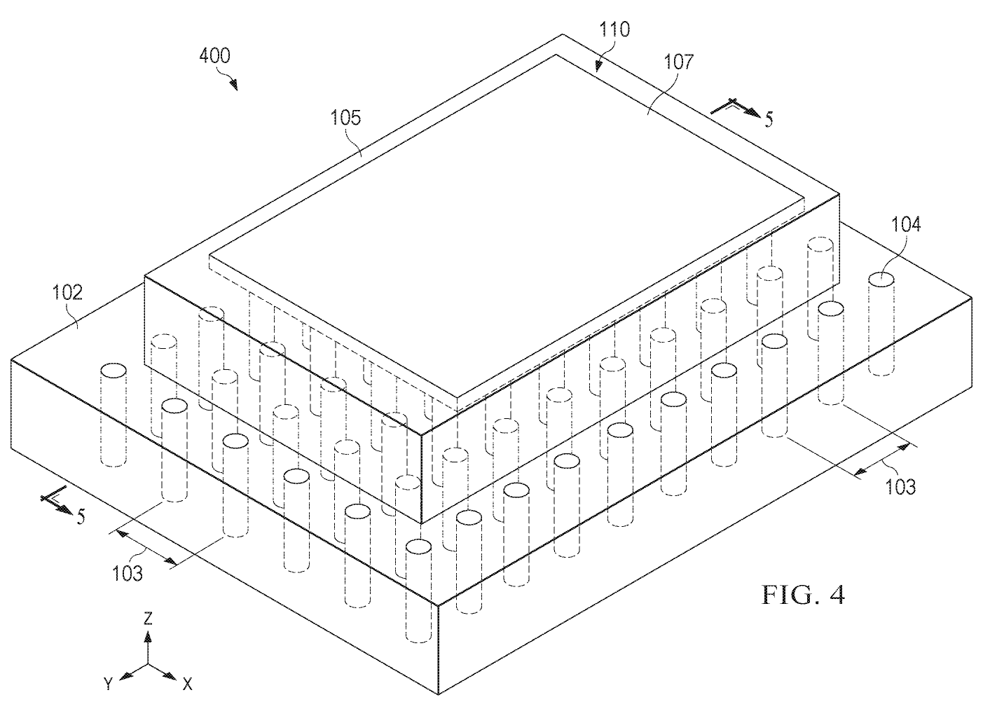

FIG. 4 is a top perspective view of an example MMIC 400 that includes a MMIC die 110 mounted to a thermally dissipative interposer 102, in accordance with at least one embodiment of the present disclosure. The MMIC 400 is similar to the MMIC 200 shown in FIG. 2, except that the active circuit plane or active circuit layer 107 of the MMIC die 110 is on the top surface of the MMIC die 110, opposite the thermally dissipative interposer 102, rather than being on the bottom surface and in direct contact with the thermally dissipative interposer 102. Instead, the substrate or wafer 105 of the MMIC die 110 is in contact with the thermally dissipative interposer 102.

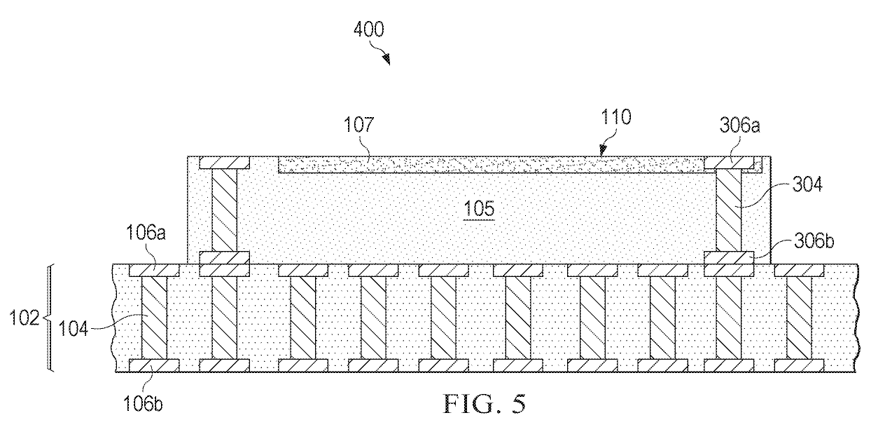

FIG. 5 is a side cross-sectional view of an example MMIC 400 that includes a MMIC die 110 bonded to a thermally dissipative interposer 102, in accordance with at least one embodiment of the present disclosure. As shown above in FIG. 5, the MMIC die 110 is mounted face-up, with the active circuit plane 107 facing away from the thermally dissipative interposer 102. This arrangement may be advantageous for higher power dissipative devices, since the contact area of the die with the heat removal path is higher for such configurations. With the active circuit plane 107 facing away from the thermally dissipative interposer 102, the active circuit plane 107 makes electrical contact with the thermally dissipative interposer 102 only through the through-semiconductor vias (TSVs) 304. As in FIG. 3, pads 306b on the bottom surface of the MMIC die 110 are in electrical contact with pads 106a on the top surface of the thermally dissipative interposer 102. However, unlike FIG. 3, the pads 306B are bonded (e.g., thermo-compression bonded) directly to the pads 106a, rather than being connected by pillars, posts, solder bumps, etc.

In the example shown in FIG. 5, one TSV 304 extends through the active circuit plane 107, such that traces or pads on the active circuit plane 107 can be in electrical contact with vias 104 in the thermally dissipative interposer 102. Such a TSV 304 could carry a power, signal, or ground connection. Another TSV 204 extends through the substrate or wafer 105 adjacent to the active circuit plane, such that the thermally dissipative interposer 102 can be in electrical contact with the top surface of the MMIC die 110, without contacting the active circuit plane 107.

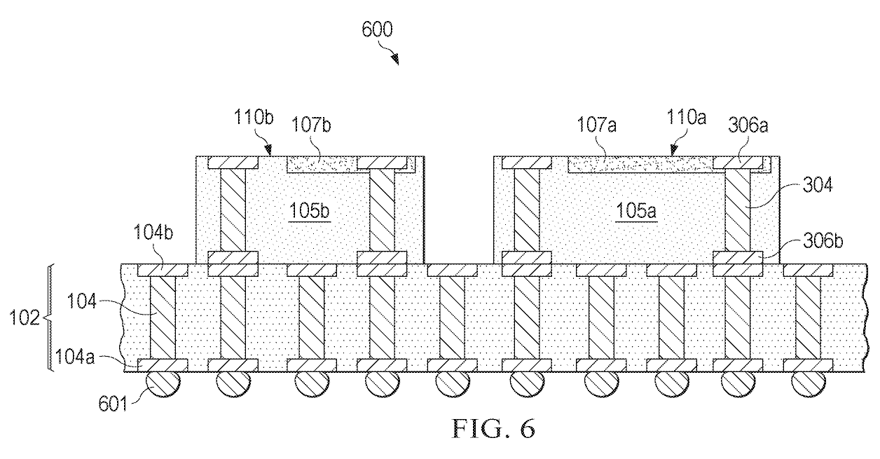

FIG. 6 is a side cross-sectional view of an example MMIC 600 that includes two MMIC dies 110a and 110b bonded to a thermally dissipative interposer 102, in accordance with at least one embodiment of the present disclosure. The two MMIC dies 110a and 110b are shown as being electrically isolated from one another. However, it is understood that the MMIC dies 110a and 110b could be wire bonded to one another to form connections between pads or traces on the active circuit plane 107a of the first die 110a and pads or traces on the active circuit plane 107b of the second die 110b.

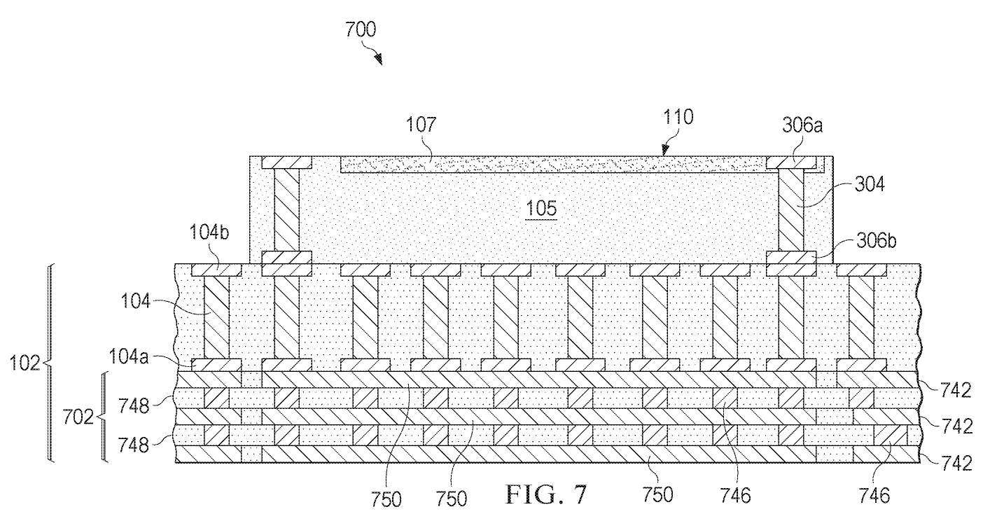

Thus, the thermally dissipative interposer 102 can be configured to support not only one, but multiple MMIC dies. These MMIC dies can all be fabricated from one semiconductor node or multiple nodes, and also support integration of MMIC dies fabricated from different semiconductor materials, such as silicon (Si), gallium arsenide (GaAs), gallium nitride (GaN), etc. Further, the thermally dissipative interposer 102 can have one or more routing layers or redistribution layers (RDLs) to support the requirements of such a multi-die interconnectivity. In an example, the active circuit plane 107a of the first die 110a could be in electrical communication with the active circuit plane 107b of the second die 110b through such routing layers or RDLs, as shown below in FIG. 7.

In the example shown in FIG. 6, the MMIC 600 also includes solder connections 601 on the bottom surface of the thermally dissipative interposer 102. These solder connections 601 may for example be solder balls with diameters of 150-200 microns, solder bumps with diameters of 100-150 microns, or solder microbumps with diameters of 50-100 microns, or otherwise. The solder connections 601 may for example facilitate electrical and mechanical connection of the thermally dissipative interposer 102 to a circuit board or other electronic component or system.

FIG. 7 is a side cross-sectional view of an example MMIC 700 that includes a MMIC die 110 bonded to a thermally dissipative interposer 102 that includes five redistribution layers (RDLs) 702, in accordance with at least one embodiment of the present disclosure. The RDLs 702 are configured to redirect electrical power, signal, and/or ground from the bottom pads 104a of the thermally dissipative interposer 102, such that some pads 104a can be connected to one another or to external devices. This arrangement maximizes the flexibility of the MMIC 700 for integration with other components, devices, or systems.

Each RDL 702 can include edge conductors 742, internal conductors 746, and/or routing layers 750, separated by insulative regions 748. Each routing layer may include one or a multitude of traces for connecting pads 104a with other pads 104a, or with internal conductors 746 or edge conductors 742, as will be familiar to a person of ordinary skill in the art.

Depending on the implementation, the RDLs may be manufactured as layers within, or on the surface of, the thermally dissipative interposer 102, or may be bonded (e.g., thermally or adhesively bonded) to the thermally dissipative interposer 102. The RDLs may be fabricated from the same materials as the thermally dissipative interposer 102 (e.g., SiC with copper-plated vias and pads), or may be made of different materials (e.g., Si, GaAs, or GaAn, with gold traces and pads).

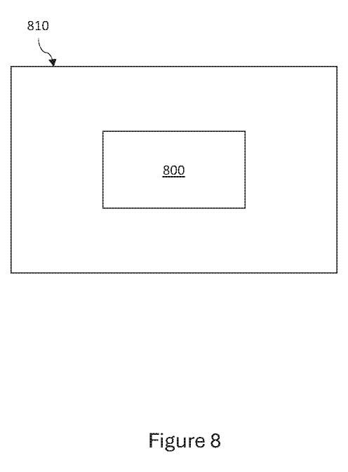

FIG. 8 is a schematic, diagrammatic view of an electronic device or a wireless device 810 comprising a MMIC 800, in accordance with at least one embodiment of the present disclosure. In some implementations, the electronic device or wireless device 810 may include, for example, but not limited to, a computer, a satellite communication device, a wi-fi device, a radar, a global position system device, or any wireless device. In one or more embodiments, the MMIC 800 may include MMIC die mounted to a thermally dissipative interposer, such as MMIC 200 of FIGS. 2-3, MMIC 400 of FIGS. 4-5, MMIC 600 of FIG. 6, MMIC 700 of FIG. 7, or other MMIC comprising an MMIC die mounted to a thermally dissipative interposer. The MMIC 800 may implement any RF component used in wireless applications, as an example, such as one or more RF power amplifiers or in a radar or radar systems; and the MMIC 800 may be coupled to other circuitry for implementing a wireless application.

Key elements of this disclosure include at least one MMIC die that has at least one through-semiconductor via (TSV) that is attached to a thermally dissipative interposer which includes at least one conductive via, conductive pad, and/or conductive trace. A plurality of any or all of these features – such as multiple TSVs, multiple dies, multiple vias, or multiple traces or routing layers within the thermally dissipative interposer (as may be realized leveraging redistribution layers – RDL – or otherwise) expressly falls within the scope of the present disclosure.

Accordingly, it can be seen that the MMIC with thermally dissipative interposer advantageously provides heat dissipation, electrical insulation, and mechanical support that is superior to existing interposers, while providing an interconnectivity capability that does not exist in current heat spreaders.

A number of variations are possible on the examples and embodiments described above. For example, circuitry may be present on both the top and bottom sides of one or more MMIC dies. The MMIC die may be a flip chip or wire bond design, or combinations thereof. More than two MMIC dies may be positioned on the thermally dissipative interposer. The number of redistribution layers (RDLs) in or on the thermally dissipative interposer can be 0, 1, 2, 3, 4, 5, or more. The MMIC die and/or thermally dissipative interposer may be made from different materials than those described herein, while still performing the functions described above. Other devices or components may be attached or bonded to pads/vias of the thermally dissipative interposer, including but not limited to wires, conductive traces, resistors, inductors, or capacitors. Instead of or in addition to conductive vias, the thermally dissipative interposer could include conductive traces or interconnects its upper surface, lower surface, or one or more sides. Multiple thermally dissipative interposers may be stacked, with or without other layers or components between them.

The logical units making up the embodiments of the technology described herein are referred to variously as objects, elements, components, modules, layers, etc. Furthermore, it should be understood that these may occur in any order, unless explicitly claimed otherwise or a specific order is inherently necessitated by the claim language.

All directional references e.g., upper, lower, inner, outer, upward, downward, left, right, lateral, front, back, top, bottom, above, below, vertical, horizontal, clockwise, counterclockwise, proximal, and distal are only used for identification purposes to aid the reader’s understanding of the claimed subject matter, and do not create limitations, particularly as to the position, orientation, or use of the MMIC with thermally dissipative interposer. Connection references, e.g., attached, coupled, connected, joined, or “in communication with” are to be construed broadly and may include intermediate members between a collection of elements and relative movement between elements unless otherwise indicated. As such, connection references do not necessarily imply that two elements are directly connected and in fixed relation to each other. The term “or” shall be interpreted to mean “and/or” rather than “exclusive or.” The word “comprising” does not exclude other elements or steps, and the indefinite article “a” or “an” does not exclude a plurality. Unless otherwise noted in the claims, stated values shall be interpreted as illustrative only and shall not be taken to be limiting.

The above specification, examples and data provide a complete description of the structure and use of exemplary embodiments of the MMIC with thermally dissipative interposer as defined in the claims. Although various embodiments of the claimed subject matter have been described above with a certain degree of particularity, or with reference to one or more individual embodiments, those skilled in the art could make numerous alterations to the disclosed embodiments without departing from the spirit or scope of the claimed subject matter.

Still other embodiments are contemplated. It is intended that all matter contained in the above description and shown in the accompanying drawings shall be interpreted as illustrative only of particular embodiments and not limiting. Changes in detail or structure may be made without departing from the basic elements of the subject matter as defined in the following claims.

What is claimed is:

1. A monolithic microwave integrated circuit (MMIC) device, comprising:
a MMIC die comprising:
an active circuit layer;
a first substrate material;
at least one conductive through-semiconductor via (TSV) extending completely through the first substrate material from a top side to a bottom side of the MMIC die;
a thermally dissipative interposer comprising:
a second substrate material different from the first substrate material and electrically insulating at an operating voltage of the MMIC die; and
at least one conductive via, pad, or trace in electrical contact with the at least one conductive TSV or the active circuit layer.

2. The MMIC device of claim 1, wherein the first substrate material is silicon, gallium arsenide, or gallium nitride or the second substrate material is silicon carbide, aluminum nitride, or diamond.

3. The MMIC device of claim 1, wherein the second substrate material has a thermal conductivity of at least at least 200 W/mK.

4. The MMIC device of claim 1, wherein the second substrate material has a fracture toughness of between 2.0 and 6.8 MPa m^{0.5}.

5. The MMIC device of claim 1, wherein the at least one conductive via, pad, or trace comprises a conductive via extending completely through the second substrate material from a top side to a bottom side of the thermally dissipative interposer; or
wherein the at least one conductive via, pad, or trace comprises a routing layer.

6. The MMIC device of claim 1, further comprising a redistribution layer attached to the thermally dissipative interposer and in electrical contact with the at least one conductive via, pad, or trace.

7. The MMIC device of claim 8, wherein the redistribution layer comprises at least one of a routing layer, an edge conductor, an internal conductor, or an insulating region.

8. The MMIC device of claim 1, wherein the at least one conductive TSV extends through the active circuit layer or wherein the at least one conductive TSV extends through the first substrate material adjacent to the active circuit layer.

9. A method for packaging a monolithic microwave integrated circuit (MMIC), the method comprising:
providing a MMIC die comprising:
an active circuit layer;
a first substrate material;
at least one conductive through-semiconductor via (TSV) extending completely through the first substrate material from a top side to a bottom side of the MMIC die;
providing a thermally dissipative interposer comprising:
a second substrate material different from the first substrate material and electrically insulating at an operating voltage of the MMIC die; and
at least one conductive via, pad, or trace; and
bonding the MMIC die to the thermally dissipative interposer such that the at least one conductive via, pad, or trace is in electrical contact with the at least one conductive TSV or the active circuit layer.

10. The method of claim 9, wherein the first substrate material is silicon, gallium arsenide, or gallium nitride, or wherein the second substrate material is silicon carbide, aluminum nitride, or diamond.

11. The method of claim 9, wherein the second substrate material has a thermal conductivity of at least at least 200 W/mK or a fracture toughness of between 2.0 and 6.8 MPa m^{0.5}.

12. The method of claim 9, wherein the at least one conductive via, pad, or trace comprises a conductive via extending completely through the second substrate material from a top side to a bottom side of the thermally dissipative interposer, or wherein the at least one conductive via, pad, or trace comprises a routing layer.

13. The method of claim 9, further comprising providing a redistribution layer attached to the thermally dissipative interposer and in electrical contact with the at least one conductive via, pad, or trace.

14. The method of claim 9, wherein the at least one conductive TSV extends through the active circuit layer or wherein the at least one conductive TSV extends through the first substrate material adjacent to the active circuit layer.

15. A wireless device comprising:
a monolithic microwave integrated circuit (MMIC) device, comprising:
a MMIC die comprising:
an active circuit layer;
a first substrate material;
at least one conductive through-semiconductor via (TSV) extending completely through the first substrate material from a top side to a bottom side of the MMIC die;
a thermally dissipative interposer comprising:
a second substrate material different from the first substrate material and electrically insulating at an operating voltage of the MMIC die; and
at least one conductive via, pad, or trace in electrical contact with the at least one conductive TSV or the active circuit layer.

16. The wireless device of claim 15, wherein the first substrate material is silicon, gallium arsenide, or gallium nitride or the second substrate material is silicon carbide, aluminum nitride, or diamond.

17. The wireless device of claim 15, wherein the second substrate material has a thermal conductivity of at least at least 200 W/mK.

18. The wireless device of claim 15, wherein the second substrate material has a fracture toughness of between 2.0 and 6.8 MPa m^{0.5}.

19. The wireless device of claim 15, wherein the at least one conductive via, pad, or trace comprises a conductive via extending completely through the second substrate material from a top side to a bottom side of the thermally dissipative interposer; or
wherein the at least one conductive via, pad, or trace comprises a routing layer.

20. The wireless device of claim 15, further comprising a redistribution layer attached to the thermally dissipative interposer and in electrical contact with the at least one conductive via, pad, or trace.
